(19) United States
(12) Patent Application Publication
(10) Pub. No.: US 2017/0077285 A1
(43) Pub. Date: Mar. 16, 2017

(54) SEMICONDUCTOR DEVICE

(71) Applicant: KABUSHIKI KAISHA TOSHIBA, Tokyo (JP)

(72) Inventors: Junichi UEHARA, Himeji Hyogo (JP); Masaru FURUKAWA, Himeji Hyogo (JP); Hiroshi KONO, Himeji Hyogo (JP); Takuma SUZUKI, Himeji Hyogo (JP)

(21) Appl. No.: 15/062,204

(22) Filed: Mar. 7, 2016

(30) Foreign Application Priority Data
Sep. 11, 2015 (JP) 2015-179132

(51) Int. Cl. H01L 29/78; H01L 29/08; H01L 29/10; H01L 29/16

(52) U.S. Cl. CPC H01L 29/7802; H01L 29/1608; H01L 29/0882; H01L 29/1095; H01L 29/0865; H01L 29/086

(57) ABSTRACT

A semiconductor device includes a SiC layer having a first surface, a gate insulating film on the first surface, a gate electrode on the gate insulating film, a first SiC region of a first conductivity type in the SiC layer, a second SiC region of a second conductivity type in the first SiC region, a third SiC region of the first conductivity type in the second SiC region, wherein a boundary between the second SiC region and the third SiC region, and the first surface forms a first angle, and a fourth SiC region of the first conductivity type in the third SiC region, having an impurity concentration of the first conductivity type higher than that of the third SiC region, wherein a boundary between the third SiC region and the fourth SiC region, and the first surface forms a second angle that is smaller than the first angle.

### CROSS-REFERENCE TO RELATED APPLICATION

This application is based upon and claims the benefit of priority from Japanese Patent Application No. 2015-179132, filed on Sep. 11, 2015, the entire contents of which are incorporated herein by reference.

### FIELD

An embodiment described herein relates generally to a semiconductor device.

### BACKGROUND

Silicon carbide (SiC) is expected to be used as the material for next-generation semiconductor devices. SiC has excellent physical properties, in that, as compared to silicon (Si), its bandgap is three times wider, breakdown electric field strength is 10 times stronger, and thermal conductivity is three times greater. By taking advantage of these characteristics, it is possible to realize a semiconductor device which has low loss and can perform an operation at high temperatures.

However, because a device which uses SiC can operate at a high voltage using the wider bandgap of the SiC, reliability of a gate insulating film in the device may be decreased as a result of a high electric field applied thereto.

### DESCRIPTION OF THE DRAWINGS

FIG. 1 is a schematic sectional view illustrating a semiconductor device according to an embodiment.

FIGS. 2-6 are each a schematic sectional view illustrating steps in the process of manufacturing the semiconductor device according to the embodiment.

FIG. 7 is a schematic sectional view illustrating a semiconductor device according to a comparative example.

### DETAILED DESCRIPTION

Embodiments provide a semiconductor device which can improve the reliability of its gate insulating film.

In general, according to one embodiment, a semiconductor device includes a SiC layer having a first surface, a gate insulating film on the first surface, a gate electrode on the gate insulating film, a first SiC region of a first conductivity type in the SiC layer, a second SiC region of a second conductivity type in the first SiC region, a third SiC region of the first conductivity type in the second SiC region, wherein a boundary between the second SiC region and the third SiC region, and the first surface forms a first angle, and a fourth SiC region of the first conductivity type in the third SiC region, having an impurity concentration of the first conductivity type higher than that of the third SiC region, wherein a boundary between the third SiC region and the fourth SiC region, and the first surface forms a second angle that is smaller than the first angle.

Hereinafter, an exemplary embodiment will be descried with reference to the drawings. In the following description, the same symbols or reference numerals will be given to the same or similar elements, and description of the elements provided will be repeated only as needed.

In addition, in the following description, notation of n⁺⁺, n⁺, n and n⁻, and p⁺⁺, p⁺, p and p⁻ represents relative levels of impurity concentrations of each conductive type. That is, n⁺⁺-type impurity concentration is higher than n⁺-type impurity concentration, n⁺-type impurity concentration is higher than n-type impurity concentration, and n⁻-type impurity concentration is lower than n-type impurity concentration. In addition, p⁺⁺-type impurity concentration is higher than p⁺-type impurity concentration, p⁺-type impurity concentration is higher than p-type impurity concentration, and p⁻-type impurity concentration is lower than p-type impurity concentration. There is a case in which n⁺-type and n⁻-type are simply described as an n-type, and p⁺-type and p⁻-type are simply described as a p-type.

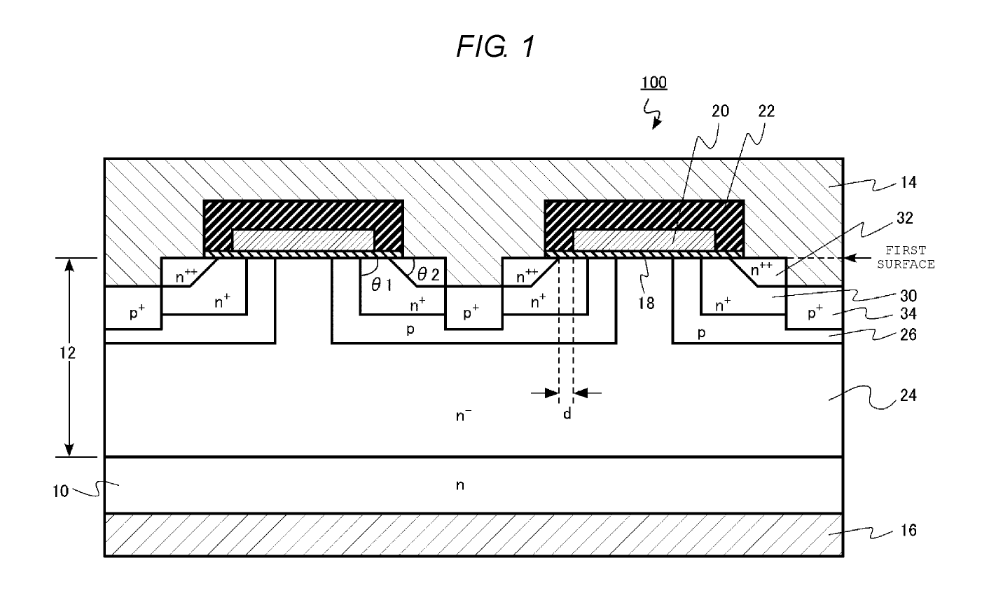

FIG. 1 is a schematic sectional view illustrating a configuration of a semiconductor device according to the embodiment, which is a metal oxide semiconductor field effect transistor (MOSFET). The MOSFET 100 includes a well region and a source region which are formed by, for example, ion injection, and is a double implantation MOSFET (DI MOSFET). The MOSFET 100 is a vertical n-channel MOSFET which uses electrons as carriers.

The MOSFET 100 includes a SiC substrate 10, a SiC layer 12, a source electrode (first electrode) 14, a drain electrode (second electrode) 16, a gate insulating film 18, a gate electrode 20, and an interlayer insulating film 22. The SiC layer 12 includes a drift region (first SiC region) 24, a well region (second SiC region) 26, a source region (third SiC region) 30, a source contact region (fourth SiC region) 32, and a well contact region 34.

The SiC substrate 10 is a SiC of single crystal. The SiC substrate 10 is, for example, 4H-SiC. In the example illustrated, an upper surface of the SiC substrate 10 is a surface inclined to an angle greater than or equal to zero degrees and smaller than or equal to eight degrees with respect to a (0001) surface, and a lower surface is a surface inclined to an angle greater than or equal to zero degrees and smaller than or equal to eight degrees with respect to (000-1) surface. The (0001) surface is referred to a silicon surface. The (000-1) surface is referred to a carbon surface.

The SiC substrate 10 is a drain region of the MOSFET 100. The SiC substrate 10 is an n-type SiC. The SiC substrate 10 contains, for example, nitride (N) as n-type impurity. The n-type impurity concentration of the SiC substrate 10 is, for example, higher than or equal to 1×10¹⁴ cm⁻³ and lower than or equal to 1×10¹⁷ cm⁻³.

It is preferable that the n-type impurity concentration of a lower surface of the SiC substrate 10 is higher than or equal to 1×10¹⁹ cm⁻³, and it is more preferable that the n-type impurity concentration of a lower surface of the SiC substrate 10 is higher than or equal to 1×10²⁰ cm⁻³, so that a contact resistance between the drain electrode 16 and the SiC substrate 10 can be reduced.

The SiC layer 12 is provided on the SiC substrate 10. The SiC layer 12 is a single crystal SiC which is formed on the SiC substrate 10 by epitaxial growth.

The SiC layer 12 has a first surface (hereinafter, will also be simply described as a surface). The first surface is, for example, a surface inclined to an angle greater than or equal to zero degrees and smaller than or equal to eight degrees with respect to a (0001) surface.

The drift region 24 is provided in the SiC layer 12. At least a portion of the drift region 24 is provided on a surface of the SiC layer 12. The drift region 24 is provided on the SiC substrate 10.

The drift region 24 is an n⁻ type SiC. The drift region 24 contains, for example, nitride (N) as an n-type impurity. The n-type impurity concentration of the drift region 24 is higher than or equal to 5×10¹⁵ cm⁻³ and lower than or equal to 2×10¹⁶ cm⁻³. A thickness of the drift region 24 is, for example, greater than or equal to 5 μm and smaller than or equal to 150 μm.

The well region 26 is provided in the SiC layer 12. The well region 26 is provided in the drift region 24. At least a portion of the well region 26 is provided on a surface of the SiC layer 12.

The well region 26 is a p-type SiC. The well region 26 functions as a channel area of the MOSFET 100.

The well region 26 contains, for example, aluminum (Al) as a p-type impurity. The p-type impurity concentration of the well region 26 is, for example, higher than or equal to 5×10¹⁵ cm⁻³ and lower than or equal to 1×10¹⁸ cm⁻³. A depth of the well region 26 is, for example, greater than or equal to 0.4 μm and smaller than or equal to 0.8 μm.

The source region 30 is provided in the SiC layer 12. The source region 30 is provided in the well region 26. At least a portion of the source region 30 is provided on a surface of the SiC layer 12.

The source region 30 is an n⁺-type SiC. The source region 30 contains, for example, phosphorous (P) as an n-type impurity. The n-type impurity concentration of the source region 30 is, for example, higher than or equal to 1×10¹⁸ cm⁻³ and lower than 1×10²⁰ cm⁻³. The n-type impurity concentration of the source region 30 is, for example, lower than or equal to 1×10¹⁹ cm⁻³. A depth of the source region 30 is smaller than the depth of the well region 26, and is, for example, greater than or equal to 0.2 μm and smaller than or equal to 0.4 μm.

A boundary between the source region 30 and the well region 26 forms a first inclined angle (θ1) from a surface of the SiC layer 12. In other words, an angle between the boundary between the source region 30 and the well region 26, and the surface of the SiC layer is the first inclined angle (θ1). The first inclined angle (θ1) is, for example, greater than or equal to 80 degrees and smaller than or equal to 90 degrees.

The source contact region 32 is provided in the SiC layer 12. The source contact region 32 is provided in the source region 30. At least a portion of the source contact region 32 is provided on the surface of the SiC layer 12.

The source contact region 32 is an n⁺⁺-type SiC. The source contact region 32 contains, for example, phosphorous (P) as n-type impurity. The n-type impurity concentration of the source contact region 32 is higher than n-type impurity of the source region 30. The n-type impurity concentration of the source contact region 32 is, for example, higher than or equal to 1×10¹⁹ cm⁻³ and lower than 1×10²² cm⁻³. A depth of the source contact region 32 is smaller than the depth of the source region 30, and is, for example, greater than or equal to 0.05 μm and smaller than or equal to 0.2 μm.

A boundary between the source contact region 32 and the source region 30 forms a second inclined angle (θ2) from the surface of the SiC layer 12. In other words, an angle between the boundary between the source contact region 32 and the source region 30, and the surface of the SiC layer is the second inclined angle (θ2).

The second inclined angle (θ2) is smaller than the first inclined angle (θ1). The second inclined angle (θ2) is, for example, greater than or equal to 45 degrees and smaller than 80 degrees. The second inclined angle (θ2) is, for example, smaller than or equal to 60 degrees.

The gate electrode 20 and the source contact region 32 are separated from each other in a direction normal to the surface of the SiC layer 12 by a distance “d” shown in FIG. 1 which is, for example, more than or equal to 0.1 μm and less than or equal to 1.0 μm.

The well contact region 34 is provided in the SiC layer 12. The well contact region 34 is provided in the well region 26. The well contact region 34 is provided to be interposed between the source regions 30.

The well contact region 34 is a p⁺-type SiC. The well contact region 34 contains, for example, aluminum (Al) as p-type impurity. Impurity concentration of the p-type impurity of the well contact region 34 is, for example, higher than or equal to 1×10¹⁸ cm⁻³ and lower than or equal to 1×10²² cm⁻³.

A depth of the well contact region 34 is smaller than a depth of the well region 26, and is, for example, greater than or equal to 0.2 μm and smaller than or equal to 0.4 μm.

The gate insulating film 18 is provided on the surface of the SiC layer 12. The gate insulating film 18 is provided on the drift region 24, the well region 26, and the source region 30. The gate insulating film 18 is, for example, a silicon oxide film. For example, a high-k insulating film (high dielectric constant insulating film) can be applied to the gate insulating film 18.

The gate electrode 20 is provided on the gate insulating film 18. The gate electrode 20 is a conductive layer. The gate electrode 20 is, for example, polycrystalline silicon which contains conductive impurity.

The interlayer insulating film 22 is provided on the gate electrode 20. The interlayer insulating film 22 is, for example, a silicon oxide film.

The well region 26 which is interposed between the source region 30 under the gate electrode 20 and the drift region 24 functions as a channel region of the MOSFET 100.

The source electrode 14 is provided on the surface of the SiC layer 12. The source electrode 14 is electrically coupled to the source contact region 32 and the well contact region 34. The source electrode 14 comes into contact with the source contact region 32 and the well contact region 34. The source electrode 14 has a function of supplying a potential to the well region 26.

The source electrode 14 is, for example, a metal. A metal which forms the SiC layer 12 is, for example, a stacked structure of titanium (Ti) and aluminum (Al). The source electrode 14 may contain metal silicide or metal carbide which comes into contact with the SiC layer 12.

The drain electrode 16 is provided on a bottom surface of the SiC substrate 10. The drain electrode 16 is in contact with and electrically coupled to the SiC substrate 10.

The drain electrode 16 is a metal such as, titanium (Ti), nickel (Ni), gold (Au) or silver (Ag), or metal silicide.

The first inclined angle (θ1) and the second inclined angle (θ2) can be measured by a scanning capacitance microscopy (SCM) method. For example, the first inclined angle (θ1) is set by drawing a tangent line of a boundary between the source region 30 and the well region 26, in the vicinity of a point at which the boundary between the source region 30 and the well region 26 intersects the first surface, from concentration profile which is observed by the SCM method, and then calculating an angle between the tangent line and the first surface. In addition, for example, the second inclined angle (θ2) is set by drawing a tangent line of a boundary between the source contact region 32 and the well region 26, in the vicinity of a point at which the boundary between the source contact region 32 and the source region 30 intersects the first surface, from the concentration profile which is observed by the SCM method, and then, calculating an angle between the tangent line and the first surface.

Impurity concentration of the impurity region can be measured by a secondary ion mass spectrometry (SIMS) method.

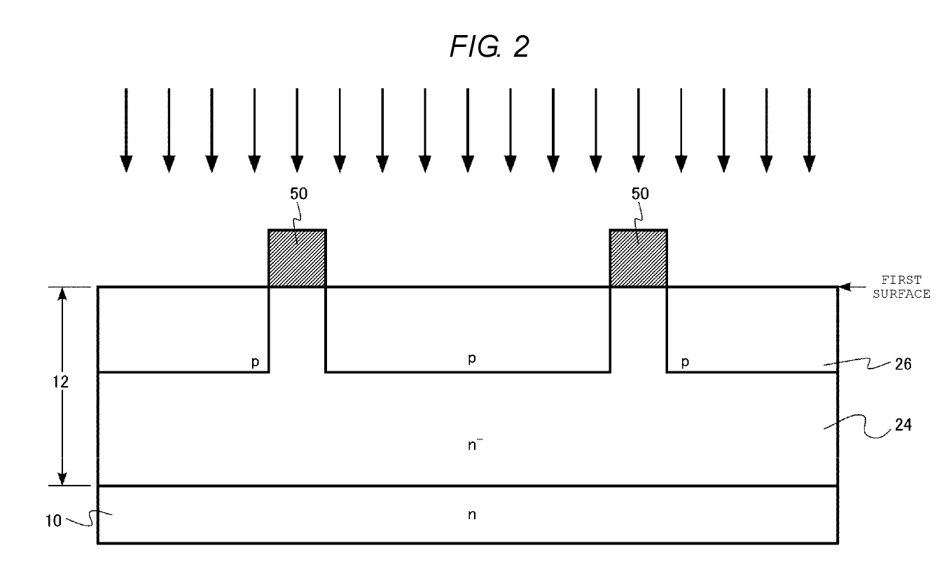

Next, a manufacturing method of the semiconductor device according to the embodiment will be described. FIGS. 2 to 6 are schematic sectional views illustrating the semiconductor device in the process of the manufacturing method of the semiconductor device according to the embodiment.

The SiC layer 12 is formed on the SiC substrate 10 by epitaxial growth. The SiC layer 12 includes a first surface (hereinafter, will also be simply described as a surface).

Subsequently, a first mask member 50 is formed on the surface of the SiC layer 12. The first mask member 50 is a silicon oxide film which is formed by, for example, a chemical vapor deposition (CVD) method.

Subsequently, ion injection of aluminum (Al), which is a p-type impurity, into the drift region 24 is performed using the first mask member 50 as a mask (FIG. 2). The well region 26 is formed by the ion injection.

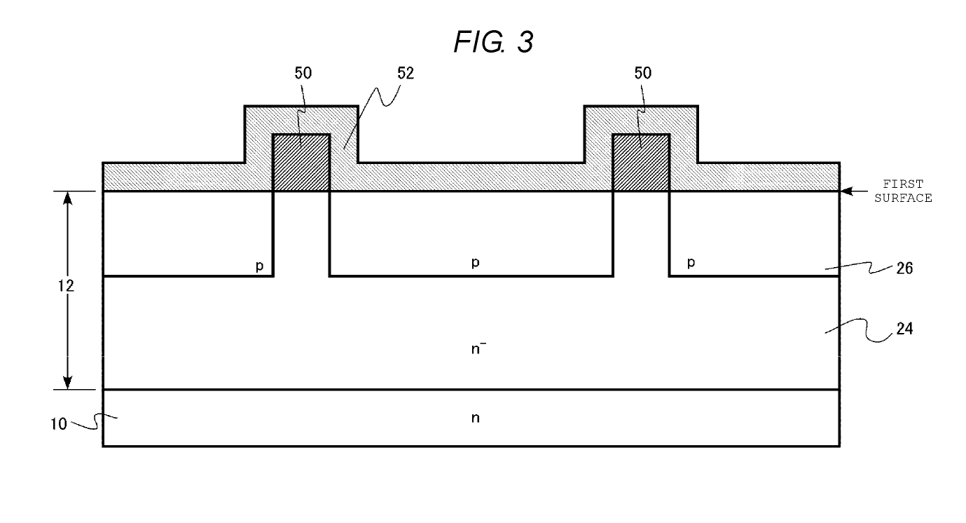

Subsequently, a second mask member 52 is deposited on the first mask member 50 and the surface of the SiC layer 12 (FIG. 3). The second mask member 52 is a silicon oxide film which is formed by, for example, a chemical vapor deposition (CVD) method.

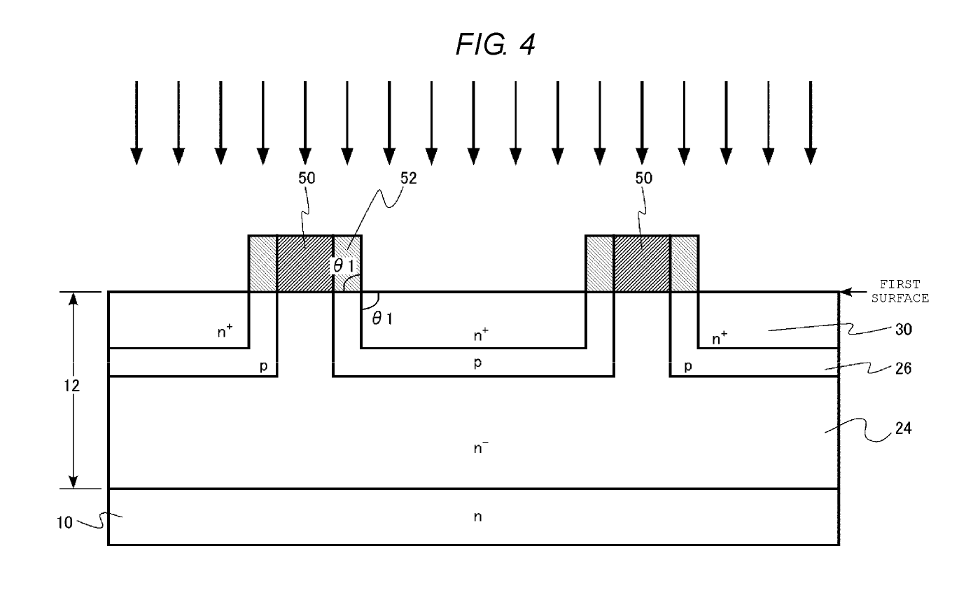

Subsequently, the second mask member 52 is etched by a reactive ion etching (RIE) method, and processing is performed such that the second mask member 52 remains on both sides of the first mask member 50. Thereafter, ion injection of phosphorous (P) which is n-type impurity into the well region 26 is performed using the first mask member 50 and the second mask member 52 as masks (FIG. 4). The source region 30 is formed by the ion injection.

For example, both side surfaces of the second mask member 52 have the first inclined angle (θ1) shown in FIG. 4. In this case, the shape of the second mask member 52 is reflected, and an angle between a boundary between the source region 30 and the well region 26, and the surface of the SiC substrate 10 becomes the first inclined angle (θ1).

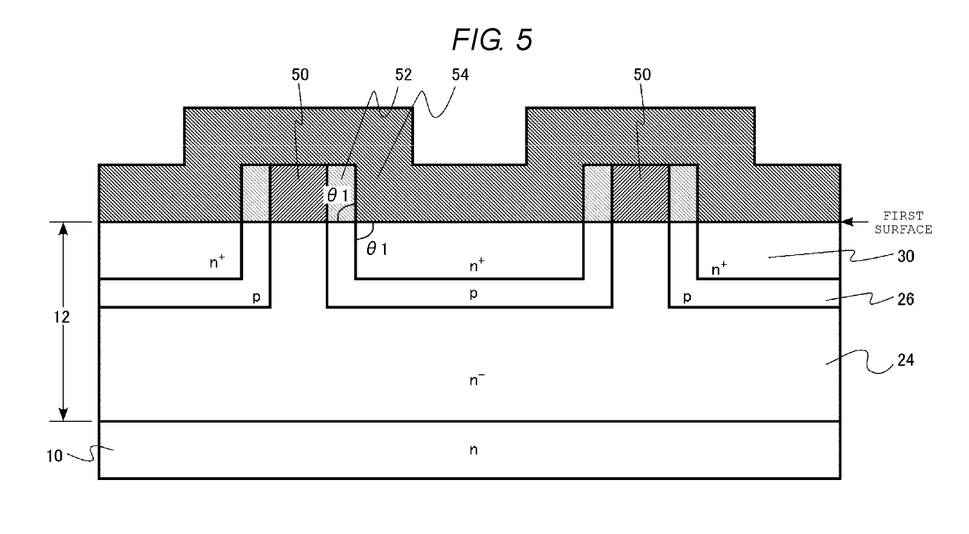

Subsequently, a third mask member 54 is deposited on the first mask member 50, the second mask member 52, and the surface of the SiC layer 12 (FIG. 5). The third mask member 54 is a silicon oxide film which is formed by, for example, the CVD method.

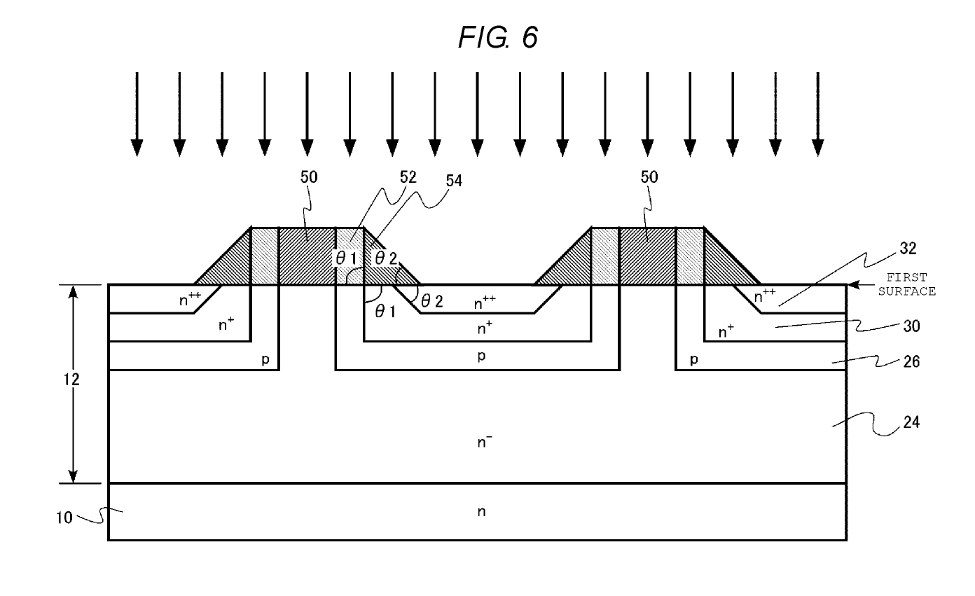

Subsequently, the third mask member 54 is etched by the RIE method, and processing is performed such that the third mask member 54 remains on both sides of the second mask member 52. Thereafter, ion injection of phosphorous (P) which is n-type impurity into the source region 30 is performed using the first mask member 50, the second mask member 52, and the third mask member 54 as masks (FIG. 6). The source contact region 32 is formed by the ion injection. A portion of source contact region 32 extends underneath mask member 54 because some of the injected phosphorus (P) ions penetrate the thin part of mask member 54.

The third mask member 54 is etched by isotropic etching, by which etching conditions are controlled such that both side surfaces of the third mask member 54 has the second inclined angle (θ2) smaller than the first inclined angle (θ1). In this case, the shape of the third mask member 54 is reflected, and an angle between a boundary between the source contact region 32 and the source region 30, and the surface of the SiC layer 12 becomes the second inclined angle (θ2).

Thereafter, the p-type well contact region 34 is formed in the SiC layer 12 by processes known in the art.

Subsequently, the first mask member 50, the second mask member 52, and the third mask member 54 are removed by wet etching. Subsequently, annealing for activating the p-type impurity and n-type impurity is performed. For example, activation annealing is performed under temperature which is higher than or equal to 1, 700° C. and lower than or equal to 1, 900° C. in inert gas atmosphere.

Diffusion speed of the p-type impurity and the n-type impurity in SiC is much slower than diffusion speed of the p-type impurity and the n-type impurity in silicon (Si). Hence, profile of the p-type impurity and the n-type impurity shortly after the ion injection according to the embodiment is maintained without a great change even after the activation annealing. Hence, the first inclined angle (θ1) and the second inclined angle (θ2) are also maintained without a great change.

Subsequently, the gate insulating film 18 is formed on the surface of the SiC substrate 10. The gate insulating film 18 is a silicon oxide film which is formed by, for example, the CVD method.

Subsequently, the gate electrode 20 is formed on the gate insulating film 18. The gate electrode 20 is, for example, polycrystalline silicon which contains conductive impurity.

Subsequently, the interlayer insulating film 22 is formed on the gate insulating film 18 and the gate electrode 20. The interlayer insulating film 22 is formed by depositing a silicon oxide film by, for example, the CVD method and thereafter, patterning the silicon oxide film.

Subsequently, the source electrode 14 is formed on the source contact region 32 and the well contact region 34. The source electrode 14 is formed by sputtering, for example, titanium (Ti) and aluminum (Al).

Subsequently, the drain electrode 16 is formed on the rear surface of the SiC substrate 10. The drain electrode 16 is formed by sputtering, for example, Ti, Ni, Au, Ag, or the like. In addition, there is a case in which the drain electrode 16 of metal silicide is formed by performing thermal processing such as, sinter or rapid thermal annealing (RTA).

By the aforementioned manufacturing method, the MOSFET 100 illustrated in FIG. 1 is formed.

Hereinafter, effects of the semiconductor device according to the embodiment will be described.

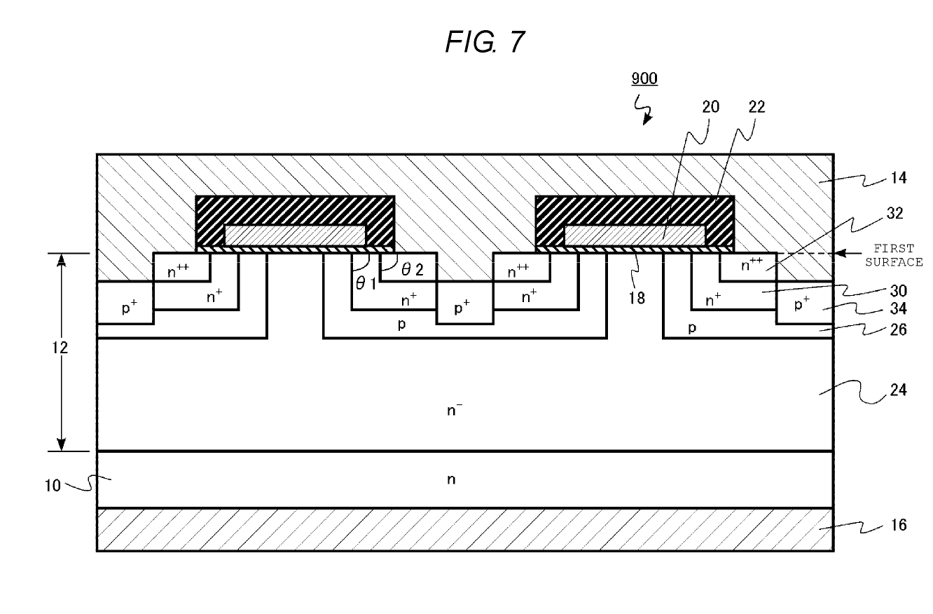

FIG. 7 is a schematic sectional view illustrating a configuration of a MOSFET 900 which is a semiconductor device according to a comparative form.

The MOSFET 900 according to the comparative form is different from the MOSFET 100 according to the embodiment in that the first inclined angle (θ1) is the same as the second inclined angle (θ2). In addition, in the MOSFET 900, the first inclined angle (θ1) and the second inclined angle (θ2) are 90 degrees.

In the MOSFET 900, in order to decrease a contact resistance between the source region 30 and the source electrode 14, the source contact region 32 in which n-type impurity concentration is higher than n-type impurity concentration of the source region 30 is provided. If n-type impurity concentration of the entire source region 30 increases, a problem occurs in which a junction leakage current caused by crystal defect increases. The crystal defect is caused by damage at the time of ion injection for forming an n-type region with a high concentration. For this reason, the MOSFET 900 employs a source structure in which the source contact region 32 with high concentration of n-type impurity is surrounded by the source region 30 with a low concentration of n-type impurity.

When the MOSFET 900 is turned off, a high voltage is applied between the gate electrode 20, the source region 30, and the source contact region 32. For this reason, a high electric field is applied to the gate insulating film 18 between the gate electrode 20, the source region 30, and the source contact region 32, and dielectric breakdown of the gate insulating film 18 becomes a problem over time. Hence, there is concern that reliability of the MOSFET 900 decreases.

An electric field which is applied to the gate insulating film 18 increases, particularly at a corner portion of the gate electrode 20. The electric field which is applied to the gate insulating film 18 from the corner portion of the gate electrode 20 depends upon the impurity concentration of the SiC layer 12 in the vicinity of a lower portion of the corner portion of the gate electrode 20. If the impurity concentration of the SiC layer 12 in the vicinity of the lower portion of the corner portion of the gate electrode 20 is increased, an electric field in the gate insulating film 18 in the vicinity of the corner portion of the gate electrode 20 increases.

Particularly, if the source contact region 32 with a high impurity concentration becomes close to the gate electrode 20 or the source contact region 32 overlaps the gate electrode 20, as in the configuration of the MOSFET 900, the electric field in the gate insulating film 18 on the corner portion of the gate electrode 20 becomes higher. Hence, there is a high possibility that reliability failure occurs due to time dependent dielectric breakdown of the gate insulating film 18.

In addition, it is considered that impurity trapped in the crystal defect in an impurity region moves into the gate insulating film 18 by an electric field, and is trapped in the impurity of the gate insulating film 18. The amount of crystal defect of the impurity region is proportional to the impurity concentration. Hence, if the impurity concentration of the SiC layer 12 in the vicinity of the lower portion of the corner portion of the gate electrode 20 is increased, there is a possibility that the amount of impurity trapped in the gate insulating film 18 is increased. For this reason, there is a high possibility that reliability failure occurs due to the dielectric breakdown of the gate insulating film. 18 over time.

In the MOSFET 100 according to the embodiment, the second inclined angle (θ2) is smaller than the first inclined angle (θ1), and thus, substantially, the impurity concentration of the SiC layer 12 in the vicinity of the lower portion of the corner portion of the gate electrode 20 is decreased. For this reason, the electric field in the gate insulating film 18 in the vicinity of the corner portion of the gate electrode 20 decreases, compared to the MOSFET 900. In addition, the amount of impurity trapped in the gate insulating film 18 is decreased, compared to the MOSFET 900. Hence, the reliability failure due to the dielectric breakdown of the gate insulating film 18 over time becomes less likely. Hence, reliability of the MOSFET 100 increases.

It is preferable that the second inclined angle (θ2) is smaller than 80 degrees, and it is more preferable that the second inclined angle (θ2) is smaller than or equal to 60 degrees, from a viewpoint that the electric field in the gate insulating film 18 in the vicinity of the corner portion of the gate electrode 20 is reduced. In addition, it is preferable that the second inclined angle (θ2) is greater than or equal to 45 degrees, from a viewpoint that formation of the second inclined angle (θ2) is stabilized.

It is preferable that the first inclined angle (θ1) is greater than or equal to 80 degrees and smaller than or equal to 90 degrees, from a viewpoint that process variation of the first inclined angle (θ1) is prevented and a channel length of the MOSFET 100, that is, a distance between the drift region 24 and the source region 30 which are immediately below the gate insulating film 18 is stabilized.

It is preferable that the gate electrode 20 and the source contact region 32 are separated from each other in a direction parallel to the surface of the SiC layer 12, from a viewpoint that impurity concentration of the SiC layer 12 in the vicinity of the lower portion of the corner portion of the gate electrode 20 is reduced.

It is preferable that the n-type impurity concentration of the source contact region 32 is higher than or equal to 1×10¹⁹ cm⁻³, and it is more preferable that the n-type impurity concentration of the source contact region 32 is higher than or equal to 1×10²⁰ cm⁻³, so that the contact resistance between the source electrode 14 and the source contact region 32 can be reduced.

It is preferable that the n-type impurity concentration of the source region 30 is lower than or equal to 5×10¹⁹ cm⁻³, and it is more preferable that the n-type impurity concentration of the source region 30 is lower than or equal to 1×10¹⁹ cm⁻³, so that the crystal defect of the source region 30 can be reduced and a junction leakage current can be reduced.

As such, according to the MOSFET 100 according to the embodiment, reliability of a gate insulating film is increased.

In the embodiment, a case in which 4H-SiC is used as a SiC substrate exemplified, but other crystal types such as 3C-SiC or 6H-SiC can also be used.

In the embodiment, an example in which nitride (N) and phosphorous (P) are used as n-type impurity is described, but arsenic (As), antimony (Sb) or the like can also be applied. In addition, an example in which aluminum (Al) is used as p-type impurity is described, but boron (B) can also be used.

In addition, in the embodiment, an example in which a vertical MOSFET is used as a semiconductor device, but the semiconductor device may include a transistor having a metal insulator semiconductor (MIS) structure, and not be limited to a vertical MOSFET. For example, an exemplary embodiment can also be applied to a horizontal MOSFET. In addition, for example, an exemplary embodiment can also be applied to a vertical insulated gate bipolar transistor (IGBT).

In addition, in the embodiment, an example in which an n-type is used as the first conductivity type and a p-type is used as the second conductivity type is described, but it is also possible to use a p-type as the first conductivity type and an n-type as the second conductive type. In this case, a transistor becomes a p-channel transistor which uses holes as carriers.

While certain embodiments have been described, these embodiments have been presented by way of example only, and are not intended to limit the scope of the invention. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a SiC layer having a first surface;
a gate insulating film on the first surface;
a gate electrode on the gate insulating film;
a first SiC region of a first conductivity type in the SiC layer;
a second SiC region of a second conductivity type in the first SiC region;
a third SiC region of the first conductivity type in the second SiC region, wherein a boundary between the second SiC region and the third SiC region, and the first surface forms a first angle; and
a fourth SiC region of the first conductivity type in the third SiC region, having an impurity concentration of the first conductivity type higher than that of the third SiC region, wherein a boundary between the third SiC region and the fourth SiC region, and the first surface forms a second angle that is smaller than the first angle.

2. The device according to claim 1, wherein near the first surface:
the second SiC region surrounds the first SiC region;
the third SiC region surrounds the second SiC region; and
the fourth SiC region surrounds the third SiC region.

3. The device according to claim 1, wherein in both a first direction parallel to the first surface and a second direction normal to the first surface, the second SiC region is between the first and third SiC regions, and the third SiC region is between the second and fourth SiC regions.

4. The device according to claim 1, wherein the gate insulating film is on the first SiC region, the second SiC region, and the third SiC region.

5. The device according to claim 1, wherein the second angle is greater than or equal to 45 degrees and smaller than 80 degrees.

6. The device according to claim 1, wherein the first angle is greater than or equal to 80 degrees.

7. The device according to claim 1, wherein the gate electrode and the fourth SiC region are separated from each other in a direction parallel to the first surface.

8. The device according to claim 1, wherein an impurity concentration of the first conductivity type of the fourth SiC region is higher than or equal to 1×10²⁰ cm⁻³.

9. The device according to claim 1, wherein the impurity concentration of the first conductivity type of the third SiC region is lower than or equal to 1×10¹⁹ cm⁻³.

10. The device according to claim 1, wherein the gate insulating film is a silicon oxide film.

11. The device according to claim 1, further comprising:
a first electrode on the fourth SiC region; and
a second electrode on an other side of the SiC layer from the first electrode.

12. A semiconductor device comprising:
a SiC layer having a first surface and a second surface on a side of the SiC layer opposite to that of the first surface;
a gate insulating film on the first surface; and
a gate electrode on the gate insulating film, wherein
the SiC layer includes a first SiC region of a first conductivity type, a second SiC region of a second conductivity type, a third SiC region of the first conductivity type, and a fourth SiC region of the first conductivity type having an impurity concentration of the first conductivity type higher than that of the third SiC region, and
a boundary between the third SiC region and the fourth SiC region near the first surface and directly underneath the gate insulating film forms a first angle with respect to the first surface, and a boundary between the second SiC region and the third SiC region near the first surface and directly underneath the gate insulating film forms a second angle that is smaller than the first angle, with respect to the first surface.

13. The device according to claim 12, wherein
the second SiC region surrounds the first SiC region;
the third SiC region surrounds the second SiC region; and
the fourth SiC region surrounds the third SiC region.

14. The device according to claim 12, wherein in both a first direction parallel to the first surface and a second direction normal to the first surface, the second SiC region is between the first and third SiC regions, and the third SiC region is between the second and fourth SiC regions.

15. The device according to claim 12, wherein the gate insulating film is on the first SiC region, the second SiC region, and the third SiC region.

16. The device according to claim 12, wherein the second angle is greater than or equal to 45 degrees and smaller than 80 degrees, and the first angle is greater than or equal to 80 degrees.

17. The device according to claim 12, wherein the gate electrode and the fourth SiC region are separated from each other in a direction parallel to the first surface.

18. The device according to claim 12, wherein an impurity concentration of the first conductivity type of the fourth SiC region is higher than or equal to 1×10²⁰ cm⁻³.

19. The device according to claim 12, wherein the impurity concentration of the first conductivity type of the third SiC region is lower than or equal to 1×10¹⁹ cm⁻³.

20. The device according to claim 19, further comprising:
a first electrode on the fourth SiC region; and
a second electrode on an other side of the SiC layer from the first electrode.
